(19) United States
(12) Patent Application Publication
(10) Pub. No.: US 2015/0198886 A1
(43) Pub. Date: Jul. 16, 2015

(54) GOLD NANO-PARTICLES COATED LARGE FILM GRAPHENE AND GRAPHENE FLAKES AND METHODS FOR FORMING THE SAME

(71) Applicants: Chung-Ping Lai, NewTaipei city (TW); Juanjuan Zhou, NewTaipei city (TW); Xi Zhang, NewTaipei city (TW)

(72) Inventors: Chung-Ping Lai, NewTaipei city (TW); Juanjuan Zhou, NewTaipei city (TW); Xi Zhang, NewTaipei city (TW)

(21) Appl. No.: 14/154,189

(22) Filed: Jan. 14, 2014

(51) Int. Cl. G03F 7/16; C23C 16/08; C23C 16/26; C23C 16/44

(52) U.S. Cl. CPC G03F 7/16; C23C 16/44; C23C 16/08; C23C 16/26

(57) ABSTRACT

A single-layer GNPs/graphene includes a carrier layer as a substrate; a graphene layer on the carrier layer; and a plurality of gold nanoparticles (GNPs) evenly distributed on the graphene layer, which formed as a GNP layer; and wherein the graphene layer and the GNP layer has the effect of UV absorption; and longitudinal sizes of the GNP layers will affect the absorbing wavelengths. For forming multi-layer GNPs/graphene, the above second and third steps can be repeated until the number of the GNP layer and graphene layer has achieved to a predetermined one. Moreover, the methods for forming above structures are provided in the present invention.

### FIELD OF THE INVENTION

The present invention relates to graphene based material, and in particular to single and multi layer GNPs/graphene structure and the method for forming the same.

### BACKGROUND OF THE INVENTION

Graphene is atomic layer thin material which has strongest known mechanical strength. Graphene is an ideal anti-bacterial layer and ideal substrate to deposition of materials and thus currently more and more applications about graphenes are developed.

Graphene can be grown by various methods and in very large area. The large area CVD grown Graphene can be transferred into any substrate including paper, plastic and glass. Graphene after transferred can be processed by using traditional metal deposition and photolithography to establish pattern consequently.

Plasmon is a quantum of plasma oscillation. The plasmon is a quasiparticle resulting from the quantization of plasma oscillations just as photons and phonons are quantization of electromagnetic and mechanical vibrations, respectively (although the photon is an elementary particle, not a quasiparticle). Thus, plasmons are collective oscillations of the free electron gas density, for example, at optical frequencies. Plasmons can couple with a photon to create another quasiparticle called a plasma polariton. Plasmonics are articles consisting of metal which is abundant of free electron gas with arrangement in the space and allow the absorption of selected spectral wavelengths and emit in same or another wavelength.

By combination of graphene and plasmonic nanostructures, the unique characteristics could be achieved including:

Graphene: very thin, easy to be transferred, easy to be process, anti-bacterial, transparent, light weight and strong.

Gold: helpful for juvenilling the skin cell

Array of Gold nanoparticles: formation of plasmonics: absorption of UV light to prevent skin damage

### SUMMARY OF THE INVENTION

The object of the present invention is to provide a single and multi layer GNPs/graphene structure and the methods for forming the same. The structures of the present invention have good UV blocking effect so as to be widely used in many industrial products.

To achieve above object, the present invention provides a single-layer GNPs/graphene comprising: a carrier layer as a substrate; a graphene layer on the carrier layer; and a plurality of gold nanoparticles (GNPs) evenly distributed on the graphene layer, which formed as a GNP layer; and wherein the graphene layer and the GNP layer has the effect of UV absorption; and longitudinal sizes of the GNP layers will affect the absorbing wavelengths.

For forming multi-layer GNPs/graphene, the above second and third steps can be repeated until the number of the GNP layer and graphene layer has achieved to a predetermined one.

Moreover, the methods for forming above structures are provided in the present invention.

### BRIEF DESCRIPTION OF THE DRAWINGS

FIG. 1 shows a single-layer GNPs/graphene structure according to the present invention.

FIG. 2 shows a multi-layer GNPs/graphene structure according to the present invention

FIGS. 3-1, 3-2 and 3-3 show the process for fabricating of graphene/GNPs structures by the AuCl chemical spray according to the present invention.

FIGS. 4-1, 4-2, 4-3, 4-4, 4-5, 4-6 and 4-7 show the holographic lithography process for fabrication of periodical GNPS according to the present invention

FIG. 5-1 is a schematic view showing the operation of single-layer GNP/graphene structure through localized surface resonance.according to the present invention.

FIG. 5-2 is a diagram showing the UV blocking effect of a single-layer GNPs/graphene structure shown in FIG. 5-1.

FIG. 6-1 is a schematic view showing the operation of a multi-layer GNP/graphene through localized surface resonance.according to the present invention.

FIG. 6-2 is a diagram showing the UV blocking effect of a multi-layer GNPs/graphene shown in FIG. 6-1.

### DETAILED DESCRIPTION OF THE PREFERRED EMBODIMENT

In order that those skilled in the art can further understand the present invention, a description will be provided in the following in details. However, these descriptions and the appended drawings are only used to cause those skilled in the art to understand the objects, features, and characteristics of the present invention, but not to be used to confine the scope and spirit of the present invention defined in the appended claims.

Structure:

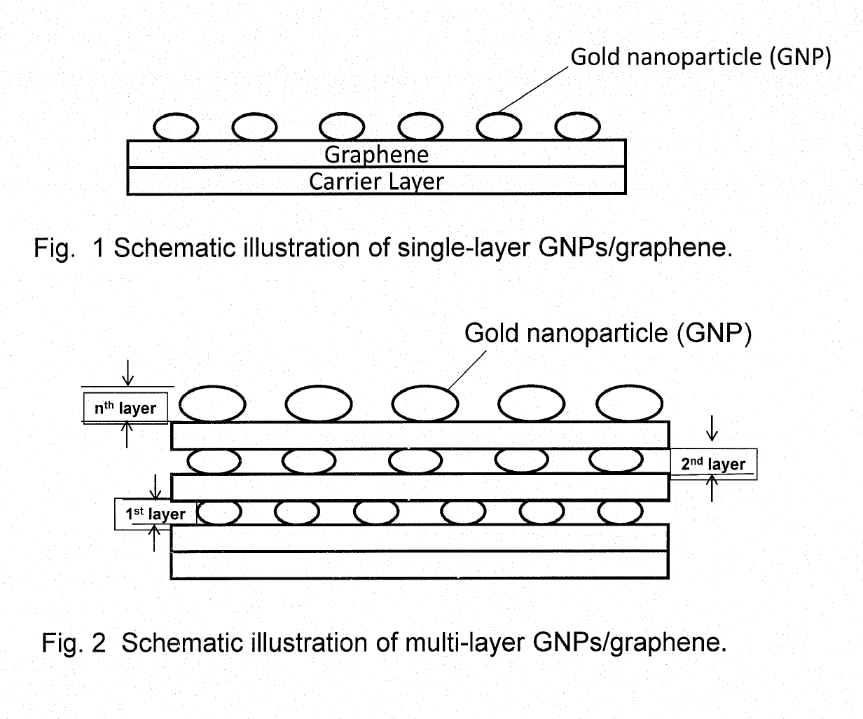

FIG. 1 and FIG. 2 illustrate the structures of the present invention.

The Single-layer GNPs/graphene structure according to the present invention comprises the following elements:

A carrier layer is as a substrate.

A graphene layer is arranged on the carrier layer.

A plurality of gold nanoparticles (GNPs) are evenly distributed on the graphene layer, which are formed as a GNP layer.

The graphene layer and the GNP layer are formed as a combining layer. The combining layer has the effect of UV absorption. Longitudinal sizes of the GNP layers will affect the absorbing wavelengths.

The Multi-layer GNPs/graphene according to the present invention comprises the following elements:

A carrier layer is as a substrate.

At least two combining layer overlaps on the carrier layer, where the sizes of GNP layers could be varied from one to another one in order to have a broad-band UV absorption ability. Other graphene based materials could be used to replace one or more graphene layers.

Fabrication process of the present invention will be described herein.

The thin-film graphene is produced by chemical vapor deposition. Graphene flakes are manufactured by exfoliation of graphite or annealing SiC, etc.

In the present invention two ways are provided for forming GNPs/graphene. They will be described herein.

Method 1 for Fabricating GNPs:

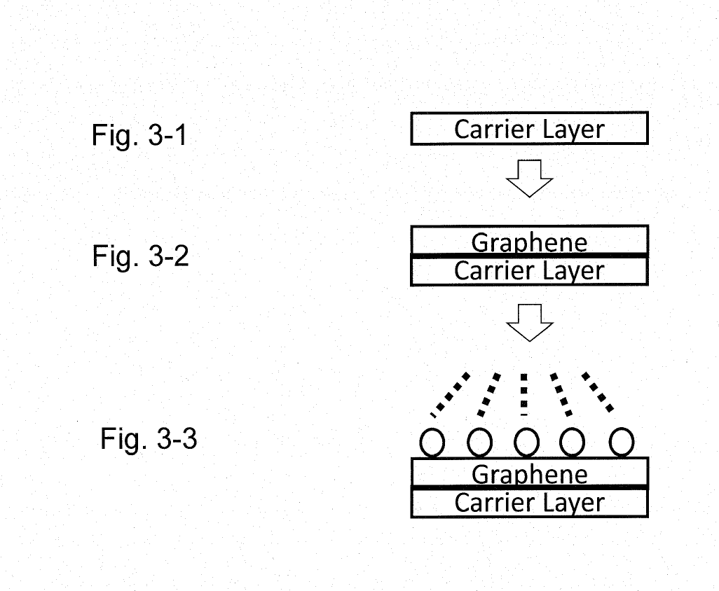

The first method for fabricating the GNPs is illustrated in FIG. 3, where the GNPs is deposited onto the graphene surface through a doping process as shown in FIGS. 3-1, 3-2, and 3-3. The process comprise the steps of:

Preparing a carrier layer as a substrate (referring to FIG. 3-1);

Transferring a graphene layer onto an upper side of the carrier layer; wherein the graphene layer is made by chemical vapor deposition (referring to FIG. 3-2);

Spraying AuCl on the upper side of the graphene layer.

For forming the Multi-layer GNPs/graphene, the second and third process can be performed repeatedly until the number of layers have achieved to a predetermined one.

As AuCl3 is sprayed on the graphene layer, the following reaction will happen:

AuCl3→AuCl+Cl2 (heating>160° C.)

3AuCl→2Au+AuCl3 (heating>420° C.)

The product of Au will be in the form of gold nano-particles. Byproducts of Cl— will be replaced by skin friendly and non-toxic components.

Method 2 for Fabricating GNPs:

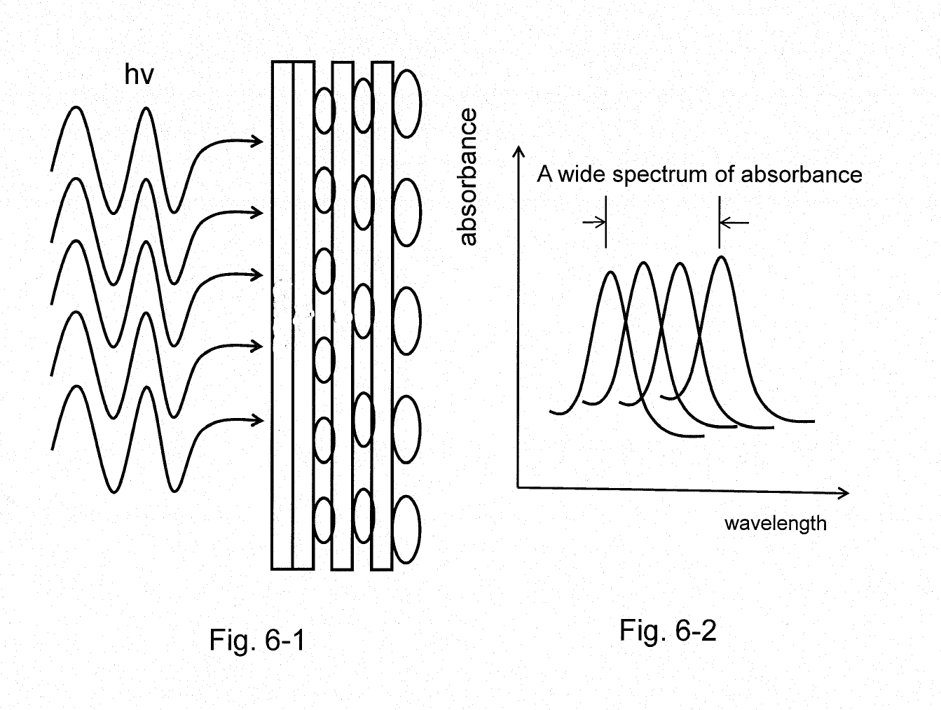

The method of interference lithography is used to fabricate periodical GNP arrays. The process is shown in FIGS. 4-1 to 4-7. The graphene/carrier substrate coated with photo resists will be exposed the interference pattern created by several laser beams. After baking and development, polymer templates will be formed. A gold layer and an adhesion layer will be deposited on the polymer/graphene/carrier structures. After deposition the polymer templates will be removed which resulting GNPs/graphene/carrier structures.

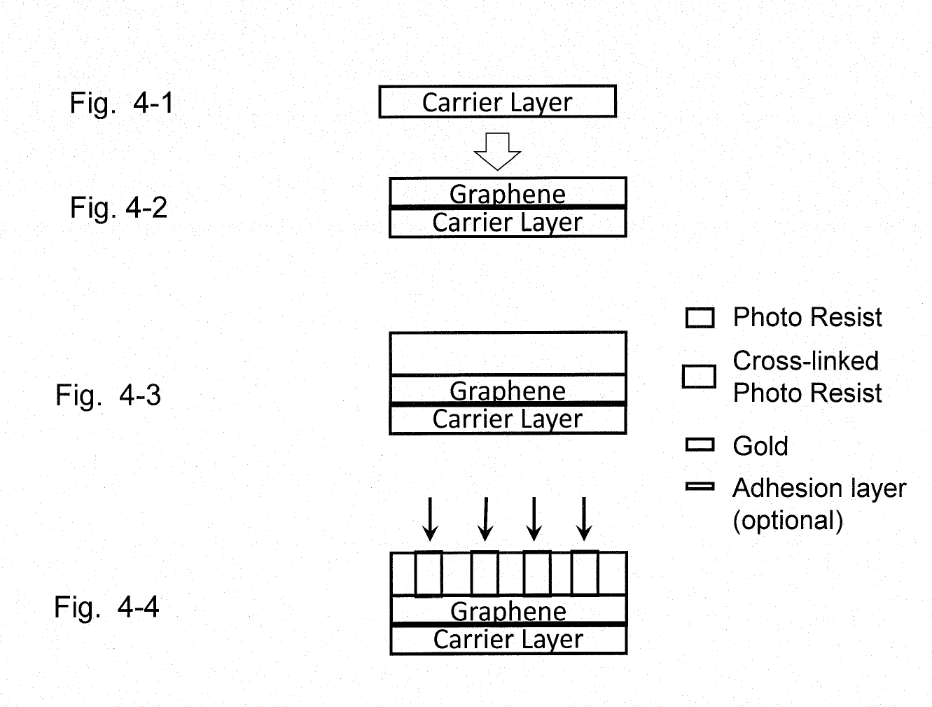

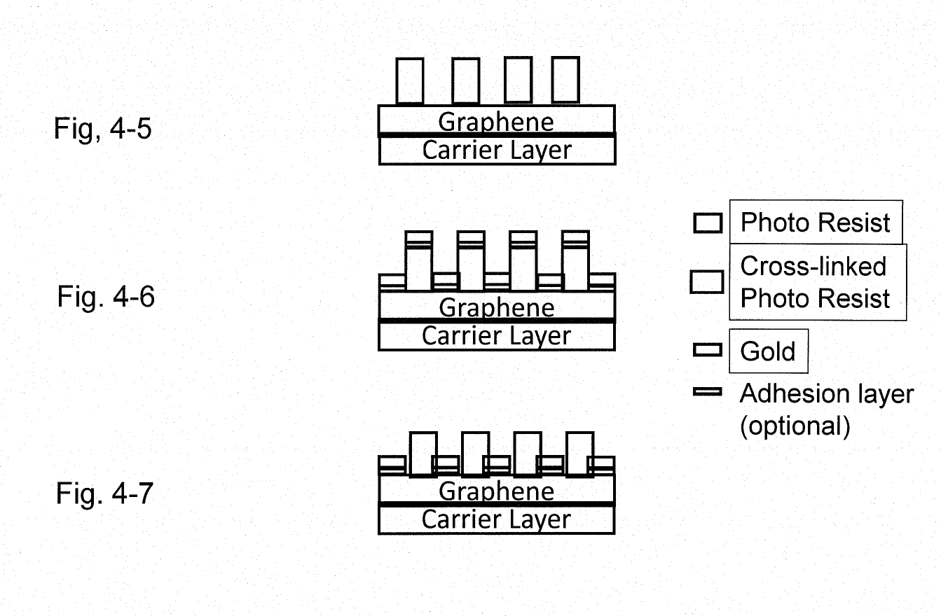

With reference to FIGS. 4-1, to 4-7, the holographic lithography process is used to fabricate period GNP of the present invention. The process includes the following steps of:

Preparing a carrier layer as a substrate (referring to FIG. 4-1);

Transferring a graphene layer onto an upper side of the carrier layer; wherein the graphene layer is made by chemical vapor deposition (referring to FIG. 4-2);

Spin-coating a photo resist layer upon an upper side of the graphene layer (referring to FIG. 4-3) so that the overall structure is formed as a combining structure; Photo resist is a photosensitive material which can be either decomposed into small molecule (positive photoresists) or cross-linked into unsoluble polymers.

Using a laser source to generate interference patterns. The wavelength of the laser is chosen according to a predetermined nanoparticle size. The interference patterns could be generated by two beams or multiple beams and then locating the interference pattern to be above the photo resist layer

Exposing the combining structure to the interference patterns, while only some part of the photo resist receiving enough light will decompose (positive photo resists) or cross-link (negative photoresists) (referring to FIG. 4-4).

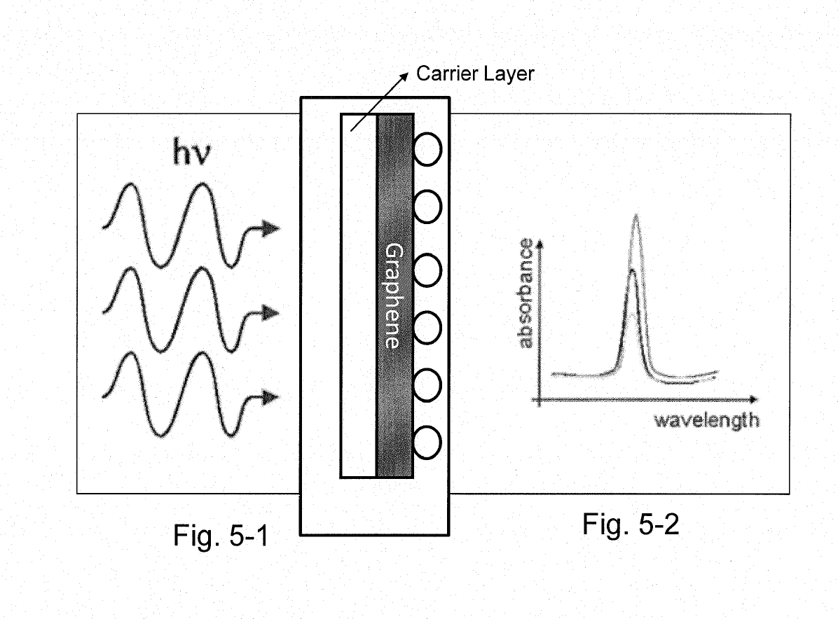

Developing the combining structure to remove the undesired photo resistance layer and then leave some cross-linked photo resistance islands on the upper side of the graphene (referring to FIG. 4-5);

Metal depositing an adhesion layer (herein a chromium layer) (this step is optional) upon the combining structure; and then further deposting gold upon the adhesion layer (referring to FIG. 4-6). The thickness of the gold layer could be tens or hundreds of nanometers.

Lifting the cross-link photo resistance islands from the upper side of the graphene layer so as to leave the adhesion layer and gold on the upper side of the graphene (referring to FIG. 4-7).

The size of the gold islands could be tens or hundreds of nanometers. As a result, a single combining layer of graphene and gold islands are formed. If multi-layers of graphene/Au islands are required, one could repeat the process several times. For forming the Multi-layer GNPs/graphene, the steps after the first step are performed repeatedly until the number of layers have achieved to a predetermined one.

Functions of GNPs:

FIGS. 5-1 and 5-2 are a schematic overview of UV blocking effect of a single-layer GNPs/graphene through localized surface resonance. The absorbance of UV depends on the GNP size, shape, and the refractive index of the surrounding medium. It is illustrated that in a specific bandwidth of the Ultraviolet spectrum, representing the resonance peak from UV light passing through the structure of the present invention, the absorbance of UV light is very effective than other frequency band of the spectrum.

FIGS. 6-1 and 6-2 shows the UV blocking effect of a multi-layer GNPs/graphene. Since the size of GNP in each layer is varied, multi-layer GNPs with different sizes will result in several resonant peaks appearing in the absorption spectrum and forms a broad-band absorption peak.

GNPs have been demonstrated to reduce the appearance of fine lines, wrinkles, sun damage and age spots. Furthermore, GNPs are noncytotoxic, nonimmunogenic, and biocompatible.

Functions of graphene or graphene based materials

Graphene based materials have superior antibacterial effect since they can kill bacterial by cell wrapping or cell trapping.

They show minimal cytotoxicity and skin irritation.

Graphene-based nanomaterials can effectively inhibit the growth of E. coli bacteria while showing minimal cytotoxicity.

The graphene layers or graphene-based material layers could be used to further blocking the UV light, since they also have strong absorption in the UV range.

When the structure of the present invention is applied to skin, the GNPs will be directly contacted with skin. Graphene will protect the GNPs, which are the functional ingredients, from bacterial. In the meantime, GNPs are able to juvenile skin cells.

As described in the present, it will be obvious that the same may be varied in many ways. Such variations are not to be regarded as a departure from the spirit and scope of the present invention, and all such modifications as would be obvious to one skilled in the art are intended to be included within the scope of the following claims.

What is claimed is:

1. A Single-layer GNPs/graphene comprising:
a carrier layer as a substrate;
a graphene layer on an upper side of the carrier layer; and
a plurality of gold nanoparticles (GNPs) evenly distributed on an upper side of the graphene layer, which formed as a GNP layer; and
wherein the graphene layer and the GNP layer has the effect of UV absorption; and longitudinal sizes of the GNP layers will affect the absorbing wavelengths.

2. A Multi-layer GNPs/graphene comprising:
a carrier layer as a substrate;
at least two combining layer overlaps on the carrier layer, each combining layer comprising:
a graphene layer on an upper side of the carrier layer; and
a plurality of gold nanoparticles (GNPs) evenly distributed on an upper side of the graphene layer, which formed as a GNP layer;
wherein the sizes of GNP layers are varied from one to another one in order to have a broad-band UV absorption.

3. A method for forming GNPs/graphene layered structure, comprising the steps of:
preparing a carrier layer as a substrate;
transferring a graphene layer onto an upper side of the carrier layer; wherein the graphene layer is made by chemical vapor deposition;
spraying AuCl3 on an upper side of the graphene layer;
wherein the following reaction will happen:
AuCl3→AuCl+Cl2 (heating>160° C.)
3AuCl→2Au+AuCl3 (heating>420° C.)
the product of Au will be in the form of gold nano-particles; and byproducts of Cl— are replaced by skin friendly and non-toxic components; and
wherein for forming the Multi-layer GNPs/graphene, the second and third process can be performed repeatedly until the number of layers have achieved to a predetermined one.

4. A method for forming GNPs/graphene layered structure, comprising the steps of
preparing a carrier layer as a substrate;
transferring a graphene layer onto an upper side of the carrier layer; wherein the graphene layer is made by chemical vapor deposition;
spin-coating a photo resist layer upon an upper side of the graphene layer so that the overall structure is formed as a combining structure; wherein photo resist is a photosensitive material which can be either decomposed into small molecule (positive photoresists) or cross-linked into unsoluble polymers;
using a laser source to generate interference patterns; wherein wavelength of the laser is chosen according to a predetermined nanoparticle size; the interference patterns could be generated by two beams or multiple beams;
locating the interference patterns to be above the photo resist layer;
exposing the combining structure to the interference patterns, while only some part of the photo resist being received enough light to decompose (positive photo resists) or cross-link (negative photoresists);
developing the combining structure to remove the undesired photo resistance layer and then leaving some cross-linked photo resistance islands on the upper side of the graphene;
metal depositing an adhesion layer (optional) upon the combining structure; and then further deposting gold upon the adhesion layer; a thickness of the gold being tens or hundreds of nanometers; and
lifting the cross-link photo resistance islands from the upper side of the graphene layer so as to leave the adhesion layer and gold on the upper side of the graphene;

5. The method of claim 4, wherein sizes of the gold islands are from tens to hundreds of nanometers.

6. The method of claim 4, wherein sizes of the gold islands are from tens to hundreds of nanometers.

7. The method of claim 4, wherein for forming Multi-layer GNPs/graphene, the steps after the first step are performed repeatedly until the number of layers have achieved to a predetermined one.
